(19) United States
(12) Patent Application Publication
(10) Pub. No.: US 2022/0263046 A1
(43) Pub. Date: Aug. 18, 2022

(54) DISPLAY APPARATUS

(71) Applicant: SAMSUNG DISPLAY CO., LTD., Yongin-si (KR)

(72) Inventor: Kyeuk Lee, Yongin-si (KR)

(21) Appl. No.: 17/479,220

(22) Filed: Sep. 20, 2021

(30) Foreign Application Priority Data
Feb. 16, 2021 (KR) 10-2021-0020684

(51) Int. Cl. H01L 51/52; H01L 27/32; H01L 51/00

(52) U.S. Cl. CPC H01L 51/5253; H01L 27/3246; G09G 3/3233; H01L 51/0097; G09G 2300/0842; H01L 27/3258

(57) ABSTRACT

A display apparatus includes a display area and a peripheral area outside the display area includes a substrate, an encapsulation layer arranged over the substrate and including at least one inorganic encapsulation layer and at least one organic encapsulation layer, a first dam portion arranged over the substrate and arranged in the peripheral area, a second dam portion arranged over the substrate and spaced apart in an outer direction from the first dam portion, and a connector arranged between the first dam portion and the second dam portion in a plan view and connecting the first dam portion to the second dam portion, where an upper surface of each of the first dam portion and the second dam portion is higher from a surface of the substrate than an upper surface of the connector is from the surface of the substrate.

This application claims priority to Korean Patent Application No. 10-2021-0020684, filed on Feb. 16, 2021, and all the benefits accruing therefrom under 35 U.S.C. § 119, the content of which in its entirety is herein incorporated by reference.

### BACKGROUND

### 1. Field

Embodiments relate to a display apparatus.

### 2. Description of the Related Art

A display apparatus visually displays data. The display apparatus may include a display area which displays an image and a peripheral area outside the display area. A driving circuit, a power wiring, etc., may be arranged in the peripheral area. The peripheral area is a region from which light is not emitted and may be a dead space.

Recently, as purposes of the display apparatus have been diversified, design that improves quality of the display apparatus is being variously attempted. Various display apparatuses are being developed with excellent characteristics such as a less thickness, a lighter weight, and low power consumption. In addition, research is being carried out into display apparatuses defining a reduced dead space and having an increased display area.

### SUMMARY

Embodiments include a display apparatus defining a reduced dead space and including an increased display area. However, such a technical problem is an example, and the invention is not limited thereto.

Additional features will be set forth in part in the description which follows and, in part, will be apparent from the description, or may be learned by practice of the presented embodiments of the invention.

In an embodiment of the invention, a display apparatus including a display area and a peripheral area outside the display area includes a substrate, an encapsulation layer arranged over the substrate and including at least one inorganic encapsulation layer and at least one organic encapsulation layer, a first dam portion arranged over the substrate, arranged in the peripheral area and including a first surface facing the substrate and a second surface opposite to the first surface of the first dam portion, a second dam portion arranged over the substrate, spaced apart in an outer direction from the first dam portion and including a first surface facing the substrate and a second surface opposite to the first surface of the second dam portion, and a connector arranged between the first dam portion and the second dam portion in a plan view, connecting the first dam portion to the second dam portion and including a first surface facing the substrate and a second surface opposite to the first surface of the connector, where the second surface of each of the first dam portion and the second dam portion is farther from a surface of the substrate than the second surface of the connector is from the surface of the substrate.

In an embodiment, the display apparatus may further include at least one insulating layer arranged between the substrate and the first dam portion and between the substrate and the second dam portion.

In an embodiment, the at least one insulating layer may include an inorganic insulating material.

In an embodiment, a hole arranged between the first dam portion and the second dam portion in the plan view may be defined in the at least one insulating layer.

In an embodiment, at least a portion of the connector may be arranged inside the hole.

In an embodiment, the connector may contact the substrate through the hole.

In an embodiment, the display apparatus may further include a first conductive layer and a second conductive layer respectively arranged between the substrate and the first dam portion and between the substrate and the second dam portion, and respectively overlapping the first dam portion and the second dam portion.

In an embodiment, the first conductive layer may be spaced apart from the second conductive layer in the plan view.

In an embodiment, the connector may overlap a separation area between the first conductive layer and the second conductive layer.

In an embodiment, the display apparatus may further include a thin-film transistor including a semiconductor layer in the display area, a gate electrode overlapping the semiconductor layer, a source electrode and a drain electrode connected to a portion of the semiconductor layer, where the first conductive layer and the second conductive layer may include a same material as a material of the gate electrode, or a material of the source electrode and the drain electrode.

In an embodiment, each of the first dam portion and the second dam portion may include a first layer including an organic insulating material, and a second layer on the first layer.

In an embodiment, the display apparatus may further include a planarization layer arranged over the substrate, a pixel electrode arranged on the planarization layer and arranged in the display area, a pixel-defining layer arranged on the pixel electrode and defining an opening that overlaps the pixel electrode, an opposite electrode arranged on the pixel-defining layer and overlapping the pixel electrode, and an intermediate layer between the pixel electrode and the opposite electrode.

In an embodiment, the first layer of each of the first dam portion and the second dam portion may include a same material as a material of the planarization layer.

In an embodiment, the second layer of each of the first dam portion and the second dam portion may include a same material as a material of the pixel-defining layer.

In an embodiment, the connector may include a same material as a material of the second layer of each of the first dam portion and the second dam portion.

In an embodiment, the connector, the second layer of the first dam portion, and the second layer of the second dam portion may be provided as one body.

In an embodiment, the connector may contact a lateral surface of the first layer of the first dam portion and a lateral surface of the first layer of the second dam portion.

In an embodiment, each of the first dam portion and the second dam portion may have a closed loop shape surrounding the display area in the plan view.

According to an embodiment of the invention, a display apparatus including a display area and a peripheral area outside the display area includes a substrate, at least one inorganic insulating layer arranged on the substrate, an organic insulating layer on the at least one inorganic insulating layer, a pixel electrode arranged on the organic insulating layer and arranged in the display area, a pixel-defining layer covering edges of the pixel electrode, an intermediate layer arranged on the pixel electrode and overlapping the pixel electrode, an opposite electrode on the intermediate layer, an encapsulation layer covering the opposite electrode and including at least one organic encapsulation layer, a plurality of dam portions arranged on the at least one inorganic insulating layer and arranged in the peripheral area, and a connector arranged between two dam portions that are adjacent to each other among the plurality of dam portions and connecting the two dam portions that are adjacent to each other, where the connector contacts a surface of the substrate through a hole defined in the at least one inorganic insulating layer.

In an embodiment, each of the plurality of dam portions may include a first layer and a second layer, the first layer including a same material as a material of the organic insulating layer, and the second layer being arranged on the first layer and including a same material as a material of the pixel-defining layer, and the connector may be provided as one body with the second layer of each of the plurality of dam portions.

In an embodiment, the display apparatus may further include a plurality of conductive layers arranged between the substrate and the plurality of dam portions and overlapping the plurality of dam portions in a plan view, where the hole may be arranged between two conductive layers that are adjacent to each other among the plurality of conductive layers.

These and/or other features will become apparent and more readily appreciated from the following description of the embodiments, the accompanying drawings, and claims.

These general and predetermined features may be implemented by a system, a method, a computer program, or a combination of a predetermined system, method, and computer program.

### BRIEF DESCRIPTION OF THE DRAWINGS

The above and other embodiments, features, and advantages of the invention will be more apparent from the following description taken in conjunction with the accompanying drawings, in which:

FIG. 1 is a schematic plan view of an embodiment of a display apparatus;

FIG. 2 is a schematic plan view of an embodiment of a display apparatus;

FIG. 3 is an equivalent circuit diagram of an embodiment of a pixel circuit of a display apparatus;

FIG. 4A is a schematic cross-sectional view of an embodiment of a display apparatus;

FIG. 4B is an enlarged cross-sectional view of an embodiment of a region C of FIG. 4A;

FIG. 5 is a schematic plan view of an embodiment of a portion of a display apparatus;

FIG. 6 is a schematic cross-sectional view of an embodiment of a display apparatus; and

FIG. 7 is a schematic cross-sectional view of an embodiment of a display apparatus.

### DETAILED DESCRIPTION

Reference will now be made in detail to embodiments, examples of which are illustrated in the accompanying drawings, where like reference numerals refer to like elements throughout. In this regard, the embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various components, such components must not be limited to the above terms. The above terms are used to distinguish one component from another component.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

When an embodiment may be implemented differently, a certain process order may be performed differently from the described order. For example, two consecutively described processes may be performed substantially at the same time or performed in an order opposite to the described order.

In the specification, “A and/or B” means A or B, or A and B. In the specification, “at least one of A and B” means A or B, or A and B.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component interposed therebetween.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

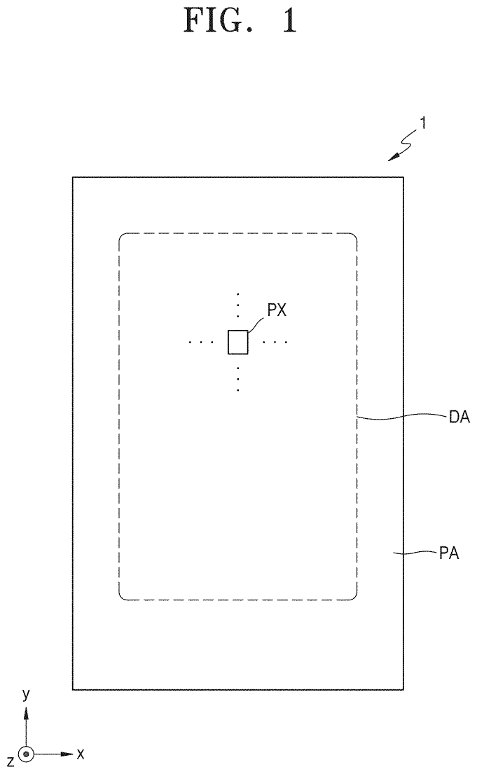

FIG. 1 is a schematic plan view of an embodiment of a display apparatus 1.

Referring to FIG. 1, the display apparatus 1 may include a display area DA and a peripheral area PA outside the display area DA. A plurality of pixels PX may be arranged in the display area DA. The display area DA may display a preset image through light emitted from the plurality of pixels PX. A pixel PX may be defined as an emission area through which a light-emitting element driven by a pixel circuit emits light. Each pixel PX may emit, for example, red, green, or blue light. In an alternative embodiment, each pixel PX may emit red, green, blue, or white light. An image may be displayed by light emitted from the pixels PX, and the light may be emitted by each of a plurality of light-emitting elements.

The peripheral area PA is an area in which an image is not displayed and may be a dead space. The peripheral area PA may be arranged outside the display area DA and may surround the display area DA entirely or partially. A driver, etc., may be arranged in the peripheral area PA, and the driver, etc., may provide an electric signal or power to the display area DA. A pad portion may be arranged in the peripheral area PA, and the pad portion may be a region to which an electronic element or a printed circuit board, etc., may be electrically connected.

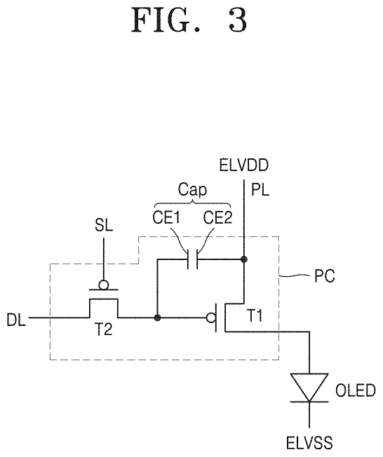

Hereinafter, though a display apparatus 1 includes an organic light-emitting diode OLED (refer to FIG. 3) as a light-emitting element, the display apparatus 1 is not limited thereto. In another embodiment, the display apparatus 1 may be a light-emitting display apparatus including an inorganic light-emitting diode, that is, an inorganic light-emitting display. An inorganic light-emitting diode may include a PN diode including inorganic semiconductor-based materials. When a voltage is applied to a PN junction diode in a forward direction, holes and electrons are injected to the PN junction diode and light of a preset color may be emitted while energy generated due to recombination of the holes and the electrons is converted to light energy. The inorganic light-emitting diode may have a width of several micrometers to several hundred micrometers. In an embodiment, the inorganic light-emitting diode may be denoted by a micro light-emitting diode. In another embodiment, the display apparatus 1 may be a quantum-dot light-emitting display.

As shown in FIG. 1, though the display apparatus 1 may have a quadrangular shape in a plan view, the invention is not limited thereto. The display apparatus 1 may have various shapes such as a polygon such as a triangle, a circular shape, an elliptical shape, and an irregular shape. In an embodiment, the display apparatus 1 may have a quadrangular shape having short sides in a first direction (e.g., an x-direction or a (−) x-direction) and long sides in a second direction (e.g., a y-direction or (−) y-direction). In another embodiment, in the display apparatus 1, the length of a side in the first direction may be the same as the length of a side in the second direction. In another embodiment, the display apparatus 1 may have long sides in the first direction and short sides in the second direction. In an embodiment, the corner of the display apparatus 1 may be round.

The display apparatus 1 may be used as a display screen of various products including televisions, notebook computers, monitors, advertisement boards, Internet of things (“IoT”) as well as portable electronic apparatuses including mobile phones, smartphones, tablet personal computers, mobile communication terminals, electronic organizers, electronic books, portable multimedia players (“PMPs”), navigations, and ultra mobile personal computers (“UMPCs”). In addition, the display apparatus 1 in an embodiment may be used in wearable devices including smartwatches, watchphones, glasses-type displays, and head-mounted displays (“HMDs”). In addition, the display apparatus 1 may be used as instrument panels for automobiles, center fascias for automobiles, or center information displays (“CIDs”) arranged on a dashboard, room mirror displays that replace side mirrors of automobiles, and a display screen arranged on the backside of front seats as an entertainment for back seats of automobiles.

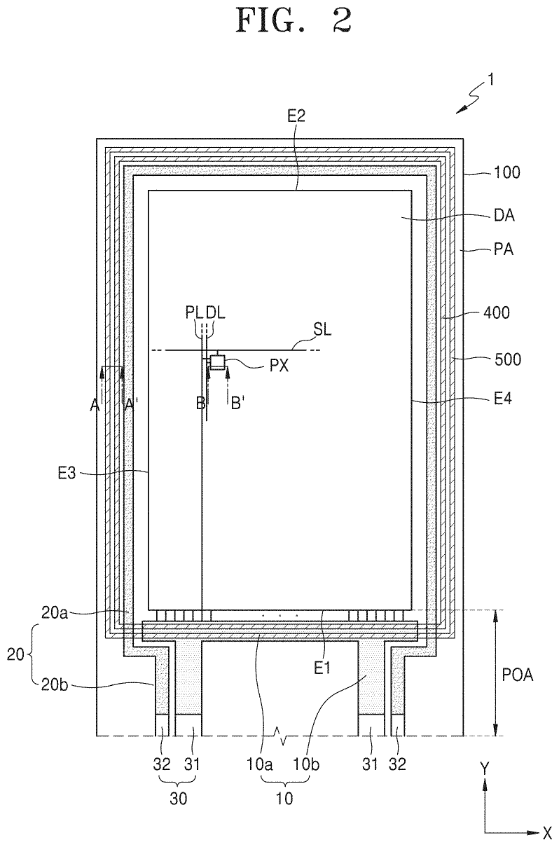

FIG. 2 is a schematic plan view of an embodiment of the display apparatus 1.

Referring to FIG. 2, the display apparatus 1 may include a substrate 100. Elements provided in the display apparatus 1 may be arranged on the substrate 100.

A plurality of pixels PX may be arranged in the display area DA of the substrate 100. As described above, the pixel PX may be defined as an emission area through which light is emitted by a light-emitting element. The light-emitting element may be driven by a pixel circuit. The pixel circuit may be connected to a scan line SL and a data line DL, the scan line SL may extend in the first direction (e.g., the x-direction or the (−) x-direction), and the data line DL may extend in the second direction (e.g., the y-direction or the (−) y-direction). The data line DL and the scan line SL may be arranged in the display area DA and may cross each other in a plan view. Here, ‘in a plan view’ may mean a figure of the display apparatus 1 when the display apparatus 1 is viewed in a direction perpendicular to one surface of the substrate 100.

Though not shown in FIG. 2, a scan driver and a data driver may be arranged in the peripheral area PA of the substrate 100, the scan driver may provide a scan signal to the scan line SL, and the data driver may provide a data signal to the data line DL.

A driving power supply line 10 and a common power supply line 20 may be arranged in the peripheral area PA of the substrate 100. The driving power supply line 10 may be arranged to correspond to a first edge E1 of the display area DA, and the common power supply line 20 may be arranged to correspond to second to fourth edges E2, E3, and E4 of the display area DA. The driving power supply line 10 may be arranged between the first edge E1 of the display area DA and a pad portion 30. The common power supply line 20 may partially surround the display area DA in a loop shape in which a region thereof corresponding to the first edge E1 is open.

The driving power supply line 10 includes a first body portion 10a extending along the first edge E1 of the display area DA. The first body portion 10a may extend along the first edge E1 in the x-direction and have a length equal to or greater than that of the first edge E1.

The first body portion 10a may be formed or provided as one body with a first connector 10b extending from the first body portion 10a in the y-direction. The first connector 10b may extend in the y-direction toward the pad portion 30 in a lead-in area POA. Here, the lead-in area POA is a region of the peripheral area PA between one edge of the substrate 100 and the first edge E1 of the display area DA that is close to the pad portion 30. The lead-in area POA may be a region from the first edge E1 of the display area DA to the pad portion 30. The first connector 10b extends from the first body portion 10a to the edge of the substrate 100 and may be connected to a first terminal 31 of the pad portion 30.

The common power supply line 20 may include a second body portion 20a extending along the second to fourth edges E2, E3, and E4 of the display area DA. The second body portion 20a may partially surround the display area DA along the second to fourth edges E2, E3, and E4 except for the first edge E1 of the display area DA. The second edge E2 of the display area DA is arranged opposite to the first edge E1. The third and fourth edges E3 and E4 connect the first edge E1 to the second edge E2 and are arranged opposite each other. The second body portion 20a may surround the display area DA and surround two opposite end portions of the first body portion 10a.

The second body portion 20a may be formed or provided as one body with a second connector 20b extending in the y-direction from the second body portion 20a. The second connector 20b may extend from the lead-in area POA in the y-direction toward the pad portion 30. The second connector 20b may extend from the lead-in area POA in parallel to the first connector 10b and be connected to a second terminal 32 of the pad portion 30.

The pad portion 30 may correspond to one end portion of the substrate 100 and be connected to a controller (not shown) through a flexible printed circuit board, etc., by not being covered with an insulating layer, etc. and being exposed. A signal or power of a controller may be provided to a pixel circuit through the pad portion 30.

The driving power supply line 10 may provide a driving power voltage to each pixel circuit, and the common power supply line 20 may provide a common power voltage to each pixel circuit. The driving power voltage may be provided to each pixel circuit through a driving voltage line PL connected to the driving power supply line 10. The common power voltage may be provided to, for example, an opposite electrode of an organic light-emitting diode. To transfer the common power voltage, the second body portion 20a of the common power supply line 20 may be connected to the opposite electrode of the organic light-emitting diode in the peripheral area PA.

A plurality of dam portions may be arranged in the peripheral area PA of the substrate 100. In an embodiment, the display apparatus 1 may include the first dam portion 400 and the second dam portion 500 arranged on the substrate 100 and arranged in the peripheral area PA. The second dam portion 500 may be spaced apart in an outer direction from the first dam portion 400. Here, the outer direction may be defined as a direction away from the display area DA of the display apparatus 1. Though it is shown in FIG. 2 that there are two dam portions, the invention is not limited thereto. In other embodiments, three or more dam portions may be provided to the display apparatus 1.

In an embodiment, the plurality of dam portions may entirely surround the display area DA in a plan view. In an embodiment, the first dam portion 400 and the second dam portion 500 may each have a closed loop shape surrounding the display area DA in a plan view. As will be described later below, an organic encapsulation layer may be arranged in the display area DA of the substrate 100 and may protect light-emitting elements in the display area DA. The organic encapsulation layer should be arranged in a desired region around the display area DA. When the organic encapsulation layer deviates from the desired region and is formed or provided to reach or approach the edge or the lateral surface of the substrate 100, the organic encapsulation layer provides a transmission path of external moisture. Accordingly, a plurality of dam portions, for example, first and second dam portions 400 and 500, may be provided such that the organic encapsulation layer is arranged in the desired region. The plurality of dam portions may surround the display area DA and control the position of an organic material that constitutes the organic encapsulation layer while the organic encapsulation layer is formed or provided.

FIG. 3 is an equivalent circuit diagram of an embodiment of a pixel circuit PC of the display apparatus 1.

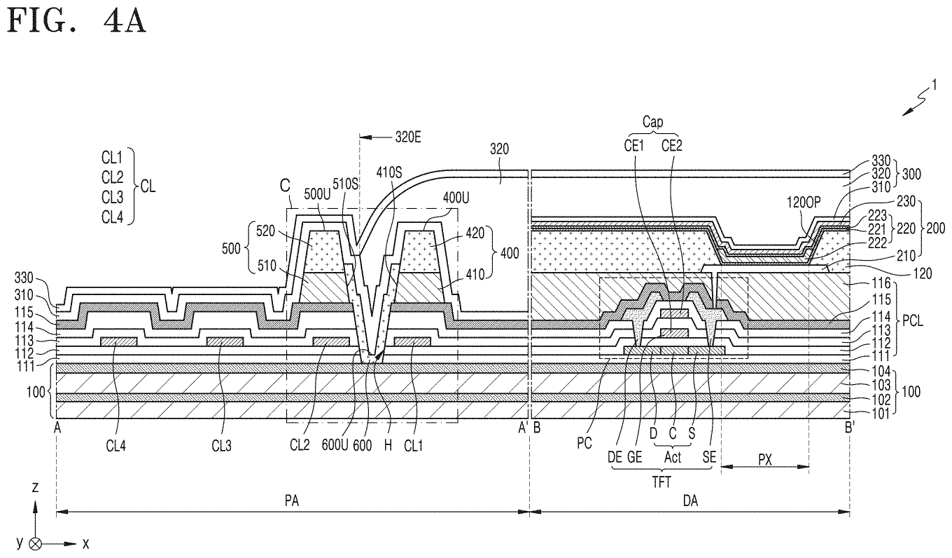

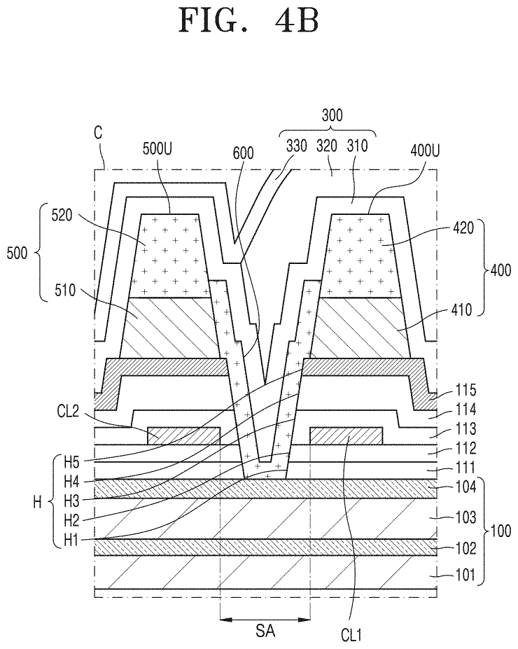

Referring to FIG. 3, the pixel circuit PC may include a plurality of thin-film transistors TFT (refer to FIG. 4A) and a storage capacitor. In an embodiment, the pixel circuit PC may include a first thin-film transistor T1, a second thin-film transistor T2, and a storage capacitor Cap.

The second thin-film transistor T2 serves as a switching thin-film transistor, is connected to the scan line SL and the data line DL, and may transfer a data voltage (or a data signal) to the first thin-film transistor T1 based on a switching voltage (or a switching signal) input from the scan line SL. The data voltage may be input from the data line DL.

The storage capacitor Cap may be connected to the second thin-film transistor T2 and the driving voltage line PL and may store a voltage corresponding to a difference between a voltage transferred from the second thin-film transistor T2 and a driving power voltage ELVDD supplied to the driving voltage line PL. The storage capacitor Cap may include at least two electrodes, for example, a bottom electrode CE1 and a top electrode CE2.

The first thin-film transistor T1 serves as a driving thin-film transistor, is connected to the driving voltage line PL and the storage capacitor Cap, and may control a driving current flowing to a light-emitting element from the driving voltage line PL according to the voltage stored in the storage capacitor Cap. The light-emitting element may include a light-emitting diode, for example, an organic light-emitting diode OLED. The organic light-emitting diode OLED may emit light having a preset brightness according to the driving current. An opposite electrode (e.g., a cathode) of the organic light-emitting diode OLED may receive a common power voltage ELVSS. In an embodiment, a voltage level of the common power voltage ELVSS may be lower than that of the driving power voltage ELVDD. In an embodiment, the opposite electrode (e.g., a cathode) of the organic light-emitting diode OLED may be connected to a ground to receive a voltage of 0 volt.

Though it is shown in FIG. 3 that the pixel circuit PC includes two thin-film transistors and one storage capacitor, the invention is not limited thereto. In an embodiment, the pixel circuit PC may include three or more thin-film transistors and/or two or more storage capacitors. In an embodiment, the pixel circuit PC may include seven thin-film transistors and one storage capacitor. The number of thin-film transistors and the number of storage capacitors may be variously changed depending on the design of the pixel circuit PC. For convenience of description, the case where the pixel circuit PC includes two thin-film transistors and one storage capacitor is described.

FIG. 4A is a schematically cross-sectional view of the display apparatus 1 in an embodiment, and FIG. 4B is an enlarged cross-sectional view of a region C of FIG. 4A. FIG. 4A may correspond to a cross-section of the display apparatus 1, taken along lines A-A′ and B-B′ of FIG. 2.

Referring to the display area DA of FIG. 4A, the display apparatus 1 may include a stack structure of the substrate 100, a pixel circuit layer PCL, a pixel-defining layer 120, a light-emitting element 200, and an encapsulation layer 300.

The substrate 100 may have a multi-layered structure including a base layer including a polymer resin and an inorganic layer. In an embodiment, the substrate 100 may include a base layer and a barrier layer. The base layer may include a polymer resin and the barrier layer may include an inorganic insulating layer. In an embodiment, the substrate 100 may include a first base layer 101, a first barrier layer 102, a second base layer 103, and a second barrier layer 104 that are sequentially stacked. In an embodiment, the first base layer 101 and the second base layer 103 may include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate, cellulose triacetate (“TAC”), and/or cellulose acetate propionate (“CAP”). The first barrier layer 102 and the second barrier layer 104 may include an inorganic insulating material such as silicon oxide, silicon oxynitride, and/or silicon nitride. The substrate 100 may be flexible.

The pixel circuit layer PCL may be arranged on the substrate 100. The pixel circuit layer PCL may include a pixel circuit PC including a plurality of thin-film transistors TFT and a storage capacitor Cap. For convenience of description, FIG. 4A shows a cross-section of one thin-film transistor TFT. In an embodiment, the shown thin-film transistor TFT may be the first thin-film transistor T1 (refer to FIG. 3). In addition, the pixel circuit layer PCL may include a plurality of insulating layers arranged under and/or on elements of the thin-film transistor TFT, for example, a first gate insulating layer 112, a second gate insulating layer 113, an inter-insulating layer 114, a passivation layer 115, and a first planarization layer 116.

A buffer layer 111 may reduce or block the penetration of foreign substance, moisture, or external air from below the substrate 100 and provide a flat surface on the substrate 100. In an embodiment, the buffer layer 111 may include an inorganic insulating material such as silicon oxide (SiO₂), silicon nitride (SiNₓ), or silicon oxynitride (SiON), and have a single-layered structure or a multi-layered structure including the above materials.

The thin-film transistor TFT on the buffer layer 111 may include a semiconductor layer Act. The semiconductor layer Act may include polycrystalline silicon. In an alternative embodiment, the semiconductor layer Act may include amorphous silicon, an oxide semiconductor, or an organic semiconductor. The semiconductor layer Act may include a channel region C, a drain region D, and a source region S. The drain region D and the source region S may be respectively arranged on two opposite sides of the channel region C. A gate electrode GE may overlap the channel region C.

The gate electrode GE may include a low-resistance metal material. In an embodiment, the gate electrode GE may include a conductive material including molybdenum (Mo), aluminum (Al), copper (Cu), or titanium (Ti) and have a single-layered structure or a multi-layered structure including the above materials.

In an embodiment, the first gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, the second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The top electrode CE2 of the storage capacitor Cap may be arranged on the second gate insulating layer 113. The top electrode CE2 may overlap the gate electrode GE therebelow. In this case, the gate electrode GE and the top electrode CE2 overlapping each other with the second gate insulating layer 113 therebetween may constitute the storage capacitor Cap. That is, the gate electrode GE may serve as the bottom electrode CE1 of the storage capacitor Cap.

As described above, the storage capacitor Cap and the thin-film transistor TFT may be formed or provided in an overlapping manner. In an embodiment, the storage capacitor Cap may not overlap the thin-film transistor TFT.

In an embodiment, the top electrode CE2 may include at least one of aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu) and may include a single layer or a multi-layer including the above materials.

The inter-insulating layer 114 may cover the top electrode CE2. In an embodiment, the inter-insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The inter-insulating layer 114 may include a single layer or a multi-layer including the above inorganic insulating materials.

A drain electrode DE and a source electrode SE may be arranged on the inter-insulating layer 114. The drain electrode DE and the source electrode SE may be respectively connected to the drain region D and the source region S through contact holes defined in the insulating layers therebelow. The drain electrode DE and the source electrode SE may each include a material having excellent conductivity. In an embodiment, the drain electrode DE and the source electrode SE may include a conductive material including at least one of molybdenum (Mo), aluminum (Al), copper (Cu), and titanium (Ti) and include a single layer or a multi-layer including the above materials. In an embodiment, the drain electrode DE and the source electrode SE may have a multi-layered structure of Ti/Al/Ti.

The passivation layer 115 may be arranged on the inter-insulating layer 114 and may cover the thin-film transistor TFT. In an embodiment, the passivation layer 115 may include, for example, silicon nitride (SiNₓ). Because hydrogen of silicon nitride couples to a dangling bond of the semiconductor layer Act of the thin-film transistor TFT and removes a defect site of the semiconductor layer Act, the characteristics of the thin-film transistor TFT may be improved. In addition, the passivation layer 115 may extend to the peripheral area PA. Though not shown in FIG. 4A, the passivation layer 115 may cover the edge or the lateral surface of the common power supply line 20 (refer to FIG. 2) arranged in the peripheral area PA. Through this, the lateral surface of the common power supply line 20 may be prevented from being damaged by etchant during a process of manufacturing the display apparatus 1.

The first planarization layer 116 may be arranged on the passivation layer 115. In an embodiment, the first planarization layer 116 may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a combination thereof.

As described above, at least one inorganic insulating layer may be arranged on the substrate 100. In an embodiment, the buffer layer 111, the first gate insulating layer 112, the second gate insulating layer 113, the inter-insulating layer 114, and the passivation layer 115 may be arranged on the substrate 100. At least one organic insulating layer may be arranged on the at least one inorganic insulating layer. In an embodiment, the first planarization layer 116 may be arranged on the at least one inorganic insulating layer. As shown in FIG. 4A, the at least one inorganic insulating layer may extend from the display area DA to the peripheral area PA and be arranged not only in the display area DA but also in the peripheral area PA. Though not shown in FIG. 4A, the at least one organic insulating layer may extend from the display area DA to a portion of the peripheral area PA.

A light-emitting element 200 may be arranged on the pixel circuit layer PCL having the structure described above. In an embodiment, the light-emitting element 200 may be arranged on the first planarization layer 116. The light-emitting element 200 may be, for example, an organic light-emitting diode OLED. The light-emitting element 200 may include a stack structure of a pixel electrode 210, an intermediate layer 220, and an opposite electrode 230. The light-emitting element 200 may emit, for example, red, green, or blue light or emit red, green, blue, or white light. The light-emitting element 200 may emit light through an emission area. The emission area may be defined as a pixel PX.

The pixel electrode 210 may be electrically connected to the thin-film transistor TFT through a contact hole defined in the first planarization layer 116.

In an embodiment, the pixel electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a combination thereof. In another embodiment, the pixel electrode 210 may further include a layer on/under the reflective layer, and the layer may include ITO, IZO, ZnO, or In₂O₃.

The pixel-defining layer 120 may be arranged on the pixel electrode 210. An opening 1200P that overlaps the pixel electrode 210 may be defined in the pixel-defining layer 120. The pixel-defining layer 120 may cover the edges of the pixel electrode 210. The pixel-defining layer 120 may include an organic insulating material and/or an inorganic insulating material. The opening 1200P of the pixel-defining layer 120 may expose the central portion of the pixel electrode 210 and define the emission area of light emitted from the organic light-emitting diode OLED. In an embodiment, the size/width of the opening 1200P may correspond to the size/width of the emission area. Accordingly, the size and/or the width of the pixel PX may depend on the size and/or the width of the opening 1200P of the pixel-defining layer 120 that corresponds thereto.

The intermediate layer 220 may be arranged to overlap the pixel electrode 210 and may include an emission layer 222 corresponding to the pixel electrode 210. The intermediate layer 220 may be arranged between the pixel electrode 210 and the opposite electrode 230 described below. The emission layer 222 may include a polymer organic material or a low-molecular weight organic material that emits light having a preset color. In an alternative embodiment, the emission layer 222 may include an inorganic light-emitting material or quantum dots.

In an embodiment, the intermediate layer 220 may include a first functional layer 221 and a second functional layer 223 respectively arranged under and on the emission layer 222. The first functional layer 221 may include, for example, a hole transport layer (“HTL”), or include an HTL and a hole injection layer (“HIL”). The second functional layer 223 is arranged on the emission layer 222 and may include an electron transport layer (“ETL”) and/or an electron injection layer (“EIL”). Like the opposite electrode 230 described below, the first functional layer 221 and/or the second functional layer 223 may be common layers entirely covering the substrate 100.

The opposite electrode 230 may be arranged on the pixel electrode 210 and the pixel-defining layer 120 and may overlap the pixel electrode 210. The opposite electrode 230 may include a conductive material having a small work function. In an embodiment, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), lithium (Li), calcium (Ca), or an alloy thereof. In an alternative embodiment, the opposite electrode 230 may further include a layer on the (semi) transparent layer, the layer including ITO, IZO, ZnO, or In₂O₃. The opposite electrode 230 may be formed or provided as one body to entirely cover the substrate 100.

The encapsulation layer 300 may be arranged on the light-emitting element 200 and may cover the opposite electrode 230 of the light-emitting element 200. That is, the encapsulation layer 300 may be arranged over the substrate 100 and may cover the display area DA. Because the organic light-emitting diode OLED as the light-emitting element 200 includes an organic material, when external moisture or air is introduced to the organic light-emitting diode OLED, the organic light-emitting diode OLED may be deteriorated. The encapsulation layer 300 may protect the organic light-emitting diode OLED in the display area DA from external moisture or air.

In an embodiment, the encapsulation layer 300 may include at least one inorganic encapsulation layer and at least one organic encapsulation layer. In an embodiment, it is shown in FIG. 3 that the encapsulation layer 300 includes a stack structure of a first inorganic encapsulation layer 310, an organic encapsulation layer 320, and a second inorganic encapsulation layer 330. The first inorganic encapsulation layer 310 may cover the light-emitting element 200, the organic encapsulation layer 320 may be arranged on the first inorganic encapsulation layer 310, and the second inorganic encapsulation layer 330 may cover the organic encapsulation layer 320.

In an embodiment, the first inorganic encapsulation layer 310 and the second inorganic encapsulation layer 330 may each include at least one inorganic material among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

Because the first inorganic encapsulation layer 310 is formed or provided along a structure thereunder, the upper surface of the first inorganic encapsulation layer 310 is not flat. The organic encapsulation layer 320 may cover the first inorganic encapsulation layer 310. Unlike the first inorganic encapsulation layer 310, the organic encapsulation layer 320 may make an upper surface thereof approximately flat. In an embodiment, the organic encapsulation layer 320 may make the upper surface thereof approximately flat in the display area DA.

The organic encapsulation layer 320 may include a polymer-based material. The polymer-based material may include an acryl-based resin, an epoxy-based resin, polyimide, and polyethylene. In an embodiment, the organic encapsulation layer 320 may include acrylate. The organic encapsulation layer 320 may be formed or provided by hardening a monomer or coating a polymer. The organic encapsulation layer 320 may have transparency.

The first and second inorganic encapsulation layers 310 and 330 may be formed or provided through chemical vapor deposition (“CVD”). The organic encapsulation layer 320 may be formed or provided through a process of coating a liquid organic material on the substrate 100 and hardening the same.

As shown in FIG. 4A, the encapsulation layer 300 may extend from the display area DA to the peripheral area PA. Most of the organic encapsulation layer 320 of the encapsulation layer 300 may be arranged in the display area DA. A portion of the organic encapsulation layer 320 arranged in the peripheral area PA may be arranged in a region of the peripheral area PA that is close to the display area DA.

In the case where the organic encapsulation layer 320 reaches or approaches the edge or the lateral surface of the substrate 100, the organic encapsulation layer 320 may provide an introduction path of external moisture or air from the edge or the lateral surface of the substrate 100 and facilitate the deterioration of the organic light-emitting diode OLED. In addition, in an embodiment, a plurality of layers arranged on and under the organic encapsulation layer 320 may be attached to each other in a portion of the peripheral area PA in which the organic encapsulation layer 320 is not arranged. When the organic encapsulation layer 320 is arranged in most of the peripheral area PA, adhesive force between the plurality of layers may be weakened and thus the plurality of layers may be separated from each other. Accordingly, while the organic encapsulation layer 320 of the encapsulation layer 300 is formed or provided, a forming region of the organic encapsulation layer 320 needs to be controlled.

Referring to the peripheral area PA of FIGS. 4A and 4B, the display apparatus 1 in an embodiment may include a plurality of dam portions, arranged in the peripheral area PA of the substrate 100. In an embodiment, the display apparatus 1 may include the first dam portion 400 and the second dam portion 500. The first dam portion 400 may be spaced apart from the second dam portion 500. In an embodiment, the second dam portion 500 may be spaced apart in an outer direction from the first dam portion 400. Here, the outer direction may be defined as a direction (e.g., a (−) x-direction in FIG. 4A) away from the display area DA of the display apparatus 1. Though FIG. 4A shows two dam portions, that is, the first dam portion 400 and the second dam portion 500, the invention is not limited thereto and three or more dam portions may be provided.

In an embodiment, the first dam portion 400 and the second dam portion 500 may each have a stack structure of a plurality of layers. In an embodiment, the first dam portion 400 and the second dam portion 500 may respectively include first layers 410 and 510 and second layers 420 and 520 on the first layers 410 and 510 including an organic material. In an embodiment, the first layer 410 of the first dam portion 400 and the first layer 510 of the second dam portion 500 may each include the same material as that of the first planarization layer 116 and be arranged in the same layer as the first planarization layer 116. In an embodiment, the first layer 410 of the first dam portion 400 and the first layer 510 of the second dam portion 500 may each be arranged on the passivation layer 115. In an embodiment, the second layer 420 of the first dam portion 400 and the second layer 520 of the second dam portion 500 may each include the same material as that of the pixel-defining layer 120.

In an embodiment, at least one insulating layer may be arranged between the substrate 100 and the plurality of dam portions. The plurality of dam portions may be arranged on the at least one insulating layer. In an embodiment, at least one insulating layer may be arranged between the substrate 100 and the first dam portion 400 and between the substrate 100 and the second dam portion 500. The at least one insulating layer may include an inorganic insulating material. As shown in FIG. 4A, the at least one insulating layer may include the buffer layer 111, the first gate insulating layer 112, the second gate insulating layer 113, the inter-insulating layer 114, and/or the passivation layer 115. In an embodiment, the first dam portion 400 and the second dam portion 500 may be arranged on the passivation layer 115 arranged in the uppermost layer of the at least one insulating layer.

The first dam portion 400 and the second dam portion 500 may control a formation region of the organic encapsulation layer 320 while the organic encapsulation layer 320 of the encapsulation layer 300 is formed or provided. In an embodiment, though a liquid organic material that constitutes the organic encapsulation layer 320 is coated mainly in the display area DA, the liquid organic material may flow in the outer direction (e.g., the (−) x-direction in FIG. 4A) toward the peripheral area PA. The first dam portion 400 may primarily hinder a flow of the organic material. In the case where a portion of the organic material overflows the first dam portion 400, the second dam portion 500 may secondarily hinder the flow of the organic material that overflows. Accordingly, an edge 320E of the organic encapsulation layer 320 may be arranged inside the first dam portion 400, or as shown in FIG. 4A, the edge 320E of the organic encapsulation layer 320 may be arranged between the first dam portion 400 and the second dam portion 500. As a result, the edge 320E of the organic encapsulation layer 320 may not be arranged outside the second dam portion 500. As described above, the first dam portion 400 and the second dam portion 500 may control the region in which the organic encapsulation layer 320 is formed or provided such that the organic encapsulation layer 320 does not reach or approach the edge or the lateral surface of the substrate 100.

To reduce the area of the peripheral area PA of the display apparatus 1, that is, the dead space, the widths of the dam portions, for example, the first and second dam portions 400 and 500, need to be reduced. However, when the widths of the first and second dam portions 400 and 500 are reduced, contact areas between the first and second dam portions 400 and 500 and an insulating layer (e.g., the passivation layer 115) thereunder are reduced, and thus, adhesive force therebetween may be reduced. Accordingly, the first and second dam portions 400 and 500 may be detached (or lost) during a process of manufacturing the display apparatus 1.

In an embodiment, a connector 600 may be provided between the first and second dam portions 400 and 500 that are adjacent to each other from among the plurality of dam portions and may connect the first dam portion 400 to the second dam portion 500. In an embodiment, the connector 600 may be arranged between the first dam portion 400 and the second dam portion 500 and may connect the first dam portion 400 to the second dam portion 500. The connector 600 may connect the first dam portion 400 to the second dam portion 500 and increase the contact areas between the first dam portion 400 and the second dam portion 500 and the insulating layer thereunder, thereby reducing the possibility of detachment of the first dam portion 400 and the second dam portion 500.

Because the second layer 420 of the first dam portion 400 is arranged on the first layer 410, the width of the second layer 420 may be equal to or less than the width of the first layer 410. Likewise, the width of the second layer 520 of the second dam portion 500 may be equal to or less than the width of the first layer 510. Accordingly, the possibilities of detachment of the second layers 420 and 520 of the first dam portion 400 and the second dam portion 500 may be greater than those of the first layers 410 and 510.

In an embodiment, the connector 600 may connect the second layer 420 of the first dam portion 400 to the second layer 520 of the second dam portion 500. For this purpose, the connector 600 may include the same material as that of the second layers 420 and 520 respectively of the first dam portion 400 and the second dam portion 500. The connector 600 may be unitary as one body with the second layer 420 of the first dam portion 400 and the second layer 520 of the second dam portion 500. That is, the connector 600 and the second layers 420 and 520 respectively of the first dam portion 400 and the second dam portion 500 may be simultaneously formed or provided during the same process. In an embodiment, the connector 600 may contact a lateral surface 410S of the first layer 410 of the first dam portion 400 and a lateral surface 510S of the first layer 510 of the second dam portion 500. As described above, the connector 600 connects the second layers 420 and 520 respectively of the first dam portion 400 and the second dam portion 500 to reduce the possibilities of detachment of the second layers 420 and 520 respectively of the first dam portion 400 and the second dam portion 500. As a result, the possibilities of detachment of the first and second dam portions 400 and 500 may be reduced.

In an embodiment, upper surfaces 400U and 500U respectively of the first and second dam portions 400 and 500 and an upper surface 600U of the connector 600 may constitute a step difference. In an embodiment, the upper surfaces 400U and 500U respectively of the first and second dam portions 400 and 500 may be higher from a surface of the substrate 100 than the upper surface 600U of the connector 600 is from the surface of the substrate 100. In other words, the upper surface 600U of the connector 600 may be closer to the substrate 100 than the upper surfaces 400U and 500U respectively of the first and second dam portions 400 and 500 are to the substrate 100.

In an embodiment, to increase the step difference between the upper surface 600U of the connector 600 and the upper surfaces 400U and 500U respectively of the first and second dam portions 400 and 500, at least one insulating layer arranged between the substrate 100 and the first and second dam portions 400 and 500 may define a hole H. In an embodiment, as shown in FIG. 4B, the buffer layer 111, the first gate insulating layer 112, the second gate insulating layer 113, the inter-insulating layer 114, and the passivation layer 115 may respectively define a first hole H1, a second hole H2, a third hole H3, a fourth hole H4, and a fifth hole H5. The first to fifth holes H1, H2, H3, H4, and H5 may overlap one another and define the hole H.

In an embodiment, the hole H may be defined between the first dam portion 400 and the second dam portion 500. The connector 600 connecting the first dam portion 400 to the second dam portion 500 may overlap the hole H, and at least a portion of the connector 600 may be arranged inside the hole H. The connector 600 may contact one surface of the substrate 100 through the hole H. Through this, the step difference between the upper surface 600U of the connector 600 and the upper surfaces 400U and 500U respectively of the first and second dam portions 400 and 500 may be further increased. That is, a height difference between the upper surface 600U of the connector 600 and the upper surfaces 400U and 500U respectively of the first and second dam portions 400 and 500 may be further increased.

As a comparative example, in the case where there is no step difference between the upper surface of each of the dam portions and the upper surface of the connector, a portion of the organic material constituting the organic encapsulation layer may overflow to the outer side of the dam portions along the upper surface of the connector.

In contrast, in an embodiment, because the upper surface 600U of the connector 600 is arranged at a position lower than the upper surfaces 400U and 500U respectively of the first and second dam portions 400 and 500, the organic material may be prevented from overflowing to the outer side of the second dam portion 500 along the upper surface 600U of the connector 600. The first dam portion 400 and the second dam portion 500 may confine the organic material from flowing over the first dam portion 400 between the first dam portion 400 and the second dam portion 500, and consequently, may prevent the organic material from flowing over the second dam portion 500.

In an embodiment, the display apparatus 1 may further include a plurality of conductive layers CL arranged in the peripheral area PA of the substrate 100. In an embodiment, as shown in FIG. 4A, first to fourth conductive layers CL1, CL2, CL3, and CL4 may be provided. However, the invention is not limited thereto. Two, three, or five or more conducive layers CL may be provided.

In an embodiment, the plurality of conductive layers CL may be used as wirings which transfer an electric signal or power. In another embodiment, some of the plurality of conductive layers CL may be electrically floated and may serve as a guard ring for preventing external static electricity from being introduced into the display apparatus 1.

In an embodiment, the first to fourth conductive layers CL1, CL2, CL3, and CL4 may be arranged between the substrate 100 and the plurality of dam portions, that is, the first and second dam portions 400 and 500. In an embodiment, the first to fourth conductive layers CL1, CL2, CL3, and CL4 may be arranged between the first gate insulating layer 112 and the second gate insulating layer 113. In another embodiment, the first to fourth conductive layers CL1, CL2, CL3, and CL4 may be arranged between the buffer layer 111 and the first gate insulating layer 112, between the second gate insulating layer 113 and the inter-insulating layer 114, or between the inter-insulating layer 114 and the passivation layer 115.

In an embodiment, the first to fourth conductive layers CL1, CL2, CL3, and CL4 may include the same material as that of the gate electrode GE of the thin-film transistor TFT. In another embodiment, the first to fourth conductive layers CL1, CL2, CL3, and CL4 may include the same material as that of the source electrode SE and the drain electrode DE of the thin-film transistor TFT.

Hereinafter, for convenience of description, as shown in FIG. 4A, the case where the first to fourth conductive layers CL1, CL2, CL3, and CL4 are arranged between the first gate insulating layer 112 and the second gate insulating layer 113 and include the same material as that of the gate electrode GE of the thin-film transistor TFT is mainly described.

In an embodiment, the first conductive layer CL1 among the plurality of conductive layers CL may be arranged between the substrate 100 and the first dam portion 400 and may overlap the first dam portion 400. In addition, the second conductive layer CL2 may be arranged between the substrate 100 and the second dam portion 500 and may overlap the second dam portion 500. In an embodiment, the first conductive layer CL1 may be spaced apart from the second conductive layer CL2. A separation area SA may be defined between the first conductive layer CL1 and the second conductive layer CL2.

In an embodiment, the hole H defined in the at least one insulating layer and the connector 600 may be arranged between two conductive layers CL that are adjacent to each other among the plurality of conductive layers CL. In an embodiment, the hole H may overlap the separation area SA between the first conductive layer CL1 and the second conductive layer CL2. In addition, the connector 600 may overlap the separation area SA between the first conductive layer CL1 and the second conductive layer CL2. That is, the connector 600 may be arranged inside the hole H arranged in the separation area SA between the first conductive layer CL1 and the second conductive layer CL2 and may contact the substrate 100 through the hole H in the separation area SA.

As described above, when the first and second conductive layers CL1 and CL2 are respectively arranged below the first and second dam portions 400 and 500, the upper surfaces 400U and 500U respectively of the first and second dam portions 400 and 500 may be away from the substrate 100 by the thicknesses of the first and second conductive layers CL1 and CL2. Through this, the overflow prevention function of the organic material (the organic material constituting the organic encapsulation layer) by the first and second dam portions 400 and 500 may be further improved. In addition, the step differences between the upper surface 600U of the connector 600 and the upper surfaces 400U and 500U respectively of the first and second dam portions 400 and 500 may be further increased. Accordingly, the effect of the first and second dam portions 400 and 500 confining the organic material may be further improved.

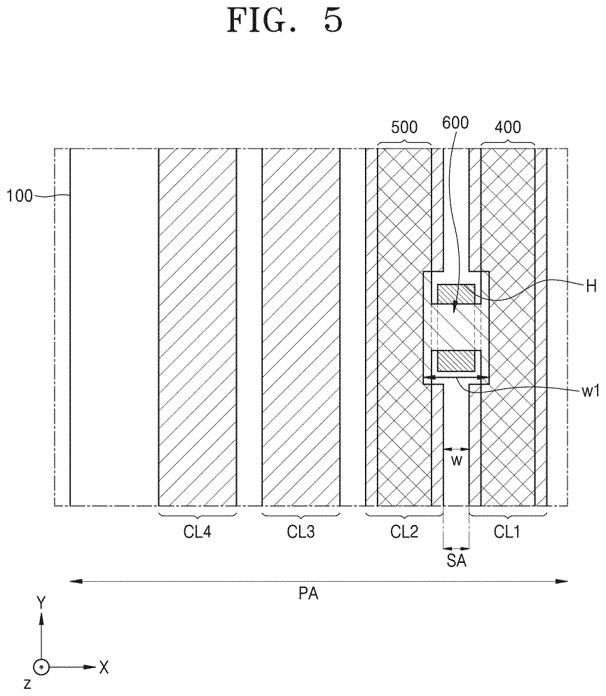

FIG. 5 is a plan view of a portion of a display apparatus. FIG. 5 shows a figure of a portion corresponding to the peripheral area PA of the display apparatus 1 in a plan view and mainly shows the arrangement of the conductive layers, the dam portions, and the connector.

Referring to FIG. 5, in the peripheral area PA of the substrate 100, the plurality of conductive layers CL may be arranged, and the plurality of conductive layers CL may extend in one direction (e.g., the y-direction) and be spaced apart from each other in a direction (e.g., the x-direction) perpendicular to the extension direction.

In an embodiment, the plurality of dam portions, that is, the first and second dam portions 400 and 500, may respectively overlap portions of the plurality of conductive layers CL. Here, ‘in a plan view’ may mean a figure of the display apparatus 1 when the display apparatus 1 is viewed in a direction perpendicular to one surface of the substrate 100. In an embodiment, the first dam portion 400 may overlap the first conductive layer CL1 in a plan view, and the second dam portion 500 may overlap the second conductive layer CL2 in a plan view.

In an embodiment, the first dam portion 400 may be spaced apart from the second dam portion 500 in a plan view, and the connector 600 may be arranged between the first dam portion 400 and the second dam portion 500. Though FIG. 5 shows one connector 600, the invention is not limited thereto. The connector 600 between the first dam portion 400 and the second dam portion 500 may be provided in plural. The plurality of connectors 600 may be spaced apart from each other with a preset interval in the extension direction of the first and second dam portions 400 and 500.

In an embodiment, in a plan view, the hole H may be defined between the first dam portion 400 and the second dam portion 500, and the connector 600 may overlap the hole H. In an embodiment, the width (e.g. the width in the y-direction) of the connector 600 may be less than the length of the hole H in one direction (e.g., the y-direction). The hole H and the connector 600 may overlap the separation area SA between the first conductive layer CL1 and the second conductive layer CL2.

In an embodiment, a width w of the separation area SA may be constant in the extension direction of the first and second conductive layers CL1 and CL2. In another embodiment, as shown in FIG. 5, the width w of the separation area SA may have a relatively large first width w1 in a region corresponding to the hole H and the connector 600. That is, a separation distance between the first conductive layer CL1 and the second conductive layer CL2 in the region corresponding to the hole H and the connector 600 may be greater than a separation distance between the first conductive layer CL1 and the second conductive layer CL2 in another region.

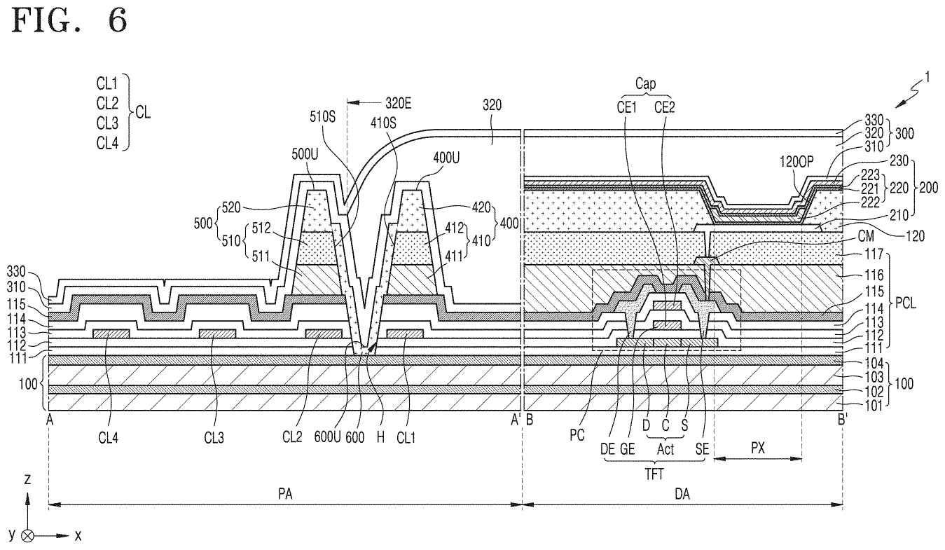

FIG. 6 is a cross-sectional view of another embodiment of the display apparatus 1. Descriptions of the same contents as those described above with reference to FIGS. 4A and 4B are omitted, and differences are mainly described below.

Referring to FIG. 6, the display apparatus 1 may further include a second planarization layer 117. The second planarization layer 117 may be arranged between the first planarization layer 116 and the pixel electrode 210. The second planarization layer 117 may include the same material as that of the first planarization layer 116 and include an organic insulating material including a general-purpose polymer such as PMMA or PS, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a combination thereof.

The pixel electrode 210 may be electrically connected to the thin-film transistor TFT through contact holes defined in the second planarization layer 117 and the first planarization layer 116 and a contact metal CM arranged on the first planarization layer 116.

In an embodiment, the first layers 410 and 510 respectively of the first and second dam portions 400 and 500 may each include a plurality of sub-layers. In an embodiment, the first layer 410 of the first dam portion 400 may include a first sub-layer 411 and a second sub-layer 412, and the second sub-layer 412 may be disposed on the first sub-layer 411. In addition, the first layer 510 of the second dam portion 500 may include a first sub-layer 511 and a second sub-layer 512, and the second sub-layer 512 may be disposed on the first sub-layer 511. Though it is described that the first layers 410 and 510 respectively of the first and second dam portions 400 and 500 include two sub-layers, the invention is not limited thereto. In another embodiment, the first layers 410 and 510 respectively of the first and second dam portions 400 and 500 may include three or more sub-layers.

In an embodiment, a first sub-layer 411 of the first layer 410 of the first dam portion 400 and a first sub-layer 511 of the first layer 510 of the second dam portion 500 may each include the same material as that of the first planarization layer 116 and be arranged in the same layer as the first planarization layer 116. In addition, a second sub-layer 412 of the first layer 410 of the first dam portion 400 and a second sub-layer 512 of the first layer 510 of the second dam portion 500 may each include the same material as that of the second planarization layer 117.

In an embodiment, the connector 600 between the first dam portion 400 and the second dam portion 500 may connect the second layer 420 of the first dam portion 400 to the second layer 520 of the second dam portion 500. The connector 600 may include the same material as that of each of the second layers 420 and 520 respectively of the first dam portion 400 and the second dam portion 500 and be formed or provided as one body with the second layers 420 and 520 respectively of the first dam portion 400 and the second dam portion 500. The connector 600 may contact the lateral surface 410S of the first layer 410 of the first dam portion 400 and the lateral surface 510S of the first layer 510 of the second dam portion 500. As shown in FIG. 6, the lateral surface 410S of the first layer 410 of the first dam portion 400 may include a lateral surface of the first sub-layer 411 of the first dam portion 400 and a lateral surface of the second sub-layer 412 of the first dam portion 400. In addition, the lateral surface 510S of the first layer 510 of the second dam portion 500 may include a lateral surface of the first sub-layer 511 of the second dam portion 500 and a lateral surface of the second sub-layer 512 of the second dam portion 500.

As shown in FIG. 6, because the first layers 410 and 510 respectively of the first and second dam portions 400 and 500 have a multi-layered structure, a step difference between the upper surface 600U of the connector 600 and the upper surfaces 400U and 500U respectively of the first and second dam portions 400 and 500 may be further increased. That is, a height difference between the upper surface 600U of the connector 600 and the upper surfaces 400U and 500U respectively of the first and second dam portions 400 and 500 may be further increased. Through this, while the organic encapsulation layer 320 is formed or provided, a possibility of the organic material overflowing on the first and second dam portions 400 and 500 may be further reduced.

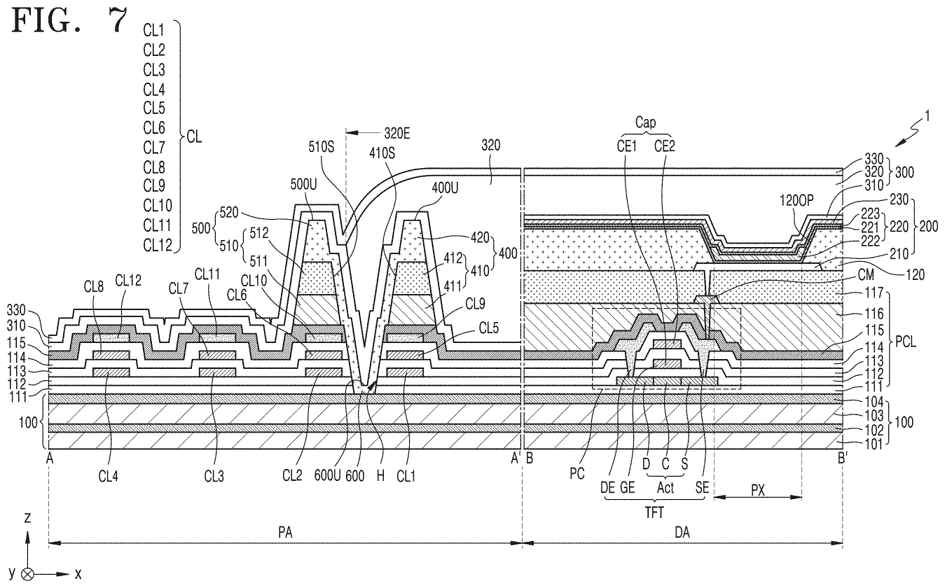

FIG. 7 is a cross-sectional view of another embodiment of a display apparatus. Descriptions of the same contents as those described above with reference to FIGS. 4A, 4B, and 6 are omitted, and differences are mainly described below.

Referring to FIG. 7, the display apparatus 1 may further include fifth to eighth conductive layers CL5, CL6, CL7, and CL8, and ninth to twelfth conductive layers CL9, CL10, CL11, and CL12. The fifth to eighth conductive layers CL5, CL6, CL7, and CL8 may be arranged between the second gate insulating layer 113 and the inter-insulating layer 114, and the ninth to twelfth conductive layers CL9, CL10, CL11, and CL12 may be arranged between the inter-insulating layer 114 and the passivation layer 115. In an embodiment, the fifth to eighth conductive layers CL5, CL6, CL7, and CL8 may include the same material as that of the top electrode CE2 of the storage capacitor Cap of the pixel circuit PC and be arranged in the same layer as the top electrode CE2. The ninth to twelfth conductive layers CL9, CL10, CL11, and CL12 may include the same material as that of the source electrode SE or the drain electrode DE of the thin-film transistor TFT and be arranged in the same layer as the source electrode SE or the drain electrode DE.

In an embodiment, the connector 600 connecting the first dam portion 400 to the second dam portion 500 may overlap a separation area between the first conductive layer CL1 and the second conductive layer CL2, a separation area between the fifth conductive layer CL5 and the sixth conductive layer CL6, and a separation area between the ninth conductive layer CL9 and the tenth conductive layer CL10.

As shown in FIG. 7, three conductive layers, that is, the first conductive layer CL1, the fifth conductive layer CL5, and the ninth conductive layer CL9 may be arranged between the first dam portion 400 and the substrate 100. Likewise, three conductive layers, that is, the second conductive layer CL2, the sixth conductive layer CL6, and the tenth conductive layer CL10 may be arranged also between the second dam portion 500 and the substrate 100. However, the invention is not limited thereto and two conductive layers or four or more conductive layers may be arranged between the first and second dam portions 400 and 500.

When the number of conductive layers arranged between the first and second dam portions 400 and 500 increases as described above, the upper surfaces 400U and 500U respectively of the first and second dam portions 400 and 500 may be further away from the substrate 100. That is, height differences between the upper surface 600U of the connector 600 and the upper surfaces 400U and 500U respectively of the first and second dam portions 400 and 500 may be further increased. Through this, while the organic encapsulation layer 320 is formed or provided, a possibility of the organic material overflowing on the first and second dam portions 400 and 500 may be further reduced.

In the embodiments, because the connector 600 connecting the first dam portion 400 to the second dam portion 500 that are adjacent to each other among the plurality of dam portions arranged in the peripheral area PA, even when the width of each of the first and second dam portions 400 and 500 is reduced, the first and second dam portions 400 and 500 may be stably formed or provided. Through this, the area (that is, the dead space) of the peripheral area PA of the display apparatus 1 may be reduced, and the area of the display area DA may be increased.

Up to this point, though description has been mainly made to the display apparatus, the invention is not limited thereto. In an embodiment, a method of manufacturing the display apparatus also falls with the scope of the invention.

In an embodiment, the display apparatus with a reduced peripheral area and an increased display area may be implemented by reducing the width of the dam portions arranged in the peripheral area. However, the scope of the invention is not limited by this effect.

It should be understood that embodiments described herein should be considered in a descriptive sense only and not for purposes of limitation. Descriptions of features or features within each embodiment should typically be considered as available for other similar features or features in other embodiments. While embodiments have been described with reference to the drawing figures, it will be understood by those of ordinary skill in the art that various changes in form and details may be made therein without departing from the spirit and scope of the invention.

What is claimed is:

1. A display apparatus including a display area and a peripheral area outside the display area, the display apparatus comprising:
a substrate;
an encapsulation layer arranged over the substrate and including at least one inorganic encapsulation layer and at least one organic encapsulation layer, the at least one inorganic encapsulation layer covering the display area;
a first dam portion arranged over the substrate, arranged in the peripheral area and including a first surface facing the substrate and a second surface opposite to the first surface of the first dam portion;
a second dam portion arranged over the substrate, spaced apart in an outer direction from the first dam portion and including a first surface facing the substrate and a second surface opposite to the first surface of the second dam portion; and
a connector arranged between the first dam portion and the second dam portion in a plan view, connecting the first dam portion to the second dam portion and including a first surface facing the substrate and a second surface opposite to the first surface of the connector,
wherein the second surface of each of the first dam portion and the second dam portion is farther from a surface of the substrate than the second surface of the connector is from the surface of the substrate.

2. The display apparatus of claim 1, further comprising at least one insulating layer arranged between the substrate and the first dam portion and between the substrate and the second dam portion.

3. The display apparatus of claim 2, wherein the at least one insulating layer includes an inorganic insulating material.

4. The display apparatus of claim 2, wherein a hole arranged between the first dam portion and the second dam portion in the plan view is defined in the at least one insulating layer.

5. The display apparatus of claim 4, wherein at least a portion of the connector is arranged inside the hole.

6. The display apparatus of claim 4, wherein the connector contacts the substrate through the hole.

7. The display apparatus of claim 2, further comprising a first conductive layer and a second conductive layer respectively arranged between the substrate and the first dam portion and between the substrate and the second dam portion, and respectively overlapping the first dam portion and the second dam portion.

8. The display apparatus of claim 7, wherein the first conductive layer is spaced apart from the second conductive layer in the plan view.

9. The display apparatus of claim 8, wherein the connector overlaps a separation area between the first conductive layer and the second conductive layer.

10. The display apparatus of claim 7, further comprising a thin-film transistor including a semiconductor layer in the display area, a gate electrode overlapping the semiconductor layer, and a source electrode and a drain electrode connected to a portion of the semiconductor layer,
wherein the first conductive layer and the second conductive layer include a same material as a material of the gate electrode, or a material of the source electrode and the drain electrode.

11. The display apparatus of claim 1, wherein each of the first dam portion and the second dam portion includes:
a first layer including an organic insulating material; and
a second layer on the first layer.

12. The display apparatus of claim 11, further comprising:
a planarization layer arranged over the substrate;
a pixel electrode arranged on the planarization layer and arranged in the display area;
a pixel-defining layer arranged on the pixel electrode and defining an opening that overlaps the pixel electrode;
an opposite electrode arranged on the pixel-defining layer and overlapping the pixel electrode; and
an intermediate layer between the pixel electrode and the opposite electrode.

13. The display apparatus of claim 12, wherein the first layer of each of the first dam portion and the second dam portion includes a same material as a material of the planarization layer.

14. The display apparatus of claim 12, wherein the second layer of each of the first dam portion and the second dam portion includes a same material as a material of the pixel-defining layer.

15. The display apparatus of claim 11, wherein the connector includes a same material as a material of the second layer of each of the first dam portion and the second dam portion.

16. The display apparatus of claim 11, wherein the connector, the second layer of the first dam portion, and the second layer of the second dam portion are provided as one body.

17. The display apparatus of claim 11, wherein the connector contacts a lateral surface of the first layer of the first dam portion and a lateral surface of the first layer of the second dam portion.

18. The display apparatus of claim 1, wherein each of the first dam portion and the second dam portion has a closed loop shape surrounding the display area in the plan view.

19. A display apparatus including a display area and a peripheral area outside the display area, the display apparatus comprising:
a substrate;
at least one inorganic insulating layer arranged on the substrate;
an organic insulating layer on the at least one inorganic insulating layer;
a pixel electrode arranged on the organic insulating layer and arranged in the display area;
a pixel-defining layer covering edges of the pixel electrode;
an intermediate layer arranged on the pixel electrode and overlapping the pixel electrode;
an opposite electrode on the intermediate layer;
an encapsulation layer covering the opposite electrode and including at least one organic encapsulation layer;
a plurality of dam portions arranged on the at least one inorganic insulating layer and arranged in the peripheral area; and
a connector arranged between two dam portions that are adjacent to each other among the plurality of dam portions and connecting the two dam portions that are adjacent to each other,
wherein the connector contacts a surface of the substrate through a hole defined in the at least one inorganic insulating layer.

20. The display apparatus of claim 19, wherein each of the plurality of dam portions includes a first layer and a second layer, the first layer including a same material as a material of the organic insulating layer, and the second layer being arranged on the first layer and including a same material as a material of the pixel-defining layer, and
the connector is provided as one body with the second layer of each of the plurality of dam portions.

21. The display apparatus of claim 19, further comprising a plurality of conductive layers arranged between the substrate and the plurality of dam portions and overlapping the plurality of dam portions in a plan view,
wherein the hole is arranged between two conductive layers that are adjacent to each other among the plurality of conductive layers.
